(19) United States
(12) Patent Application Publication
(10) Pub. No.: US 2006/0244019 A1
(43) Pub. Date: Nov. 2, 2006

(54) Semiconductor device and method of fabricating the same

(76) Inventors: Masao Sugizaki, Aizuwakamatsu-shi (JP); Katsuhiko Kabashima, Aizuwakamatsu-shi (JP); Toshiyuki Tanaka, Aizuwakamatsu-shi (JP)

Correspondence Address: INGRASSIA FISHER & LORENZ, P.C., 7150 E. CAMELBACK, STE. 325, SCOTTSDALE, AZ, 85251, US

(21) Appl. No.: 11/341,932

(22) Filed: Jan. 26, 2006

Related U.S. Application Data
(63) Continuation of application No. PCT/JP05/01084, filed on Jan. 27, 2005.

(51) Int. Cl. H01L 29/76

(52) U.S. Cl. 257/288

(57) ABSTRACT

A semiconductor device includes a semiconductor substrate having a source region and a drain region, a gate formed on the semiconductor substrate, a diode having a cathode region connected to the drain region, and a bit line connected to an anode region of the diode. The drain region and the cathode region are formed by a drain/cathode common region of an N-type semiconductor region.

### CROSS-REFERENCES TO RELATED APPLICATIONS

This is a continuation of International Application No. PCT/JP2004/001084, filed Jan. 27, 2005, which was not published in English under PCT Article 21(2).

### BACKGROUND OF THE INVENTION

1. Field of the Invention

The present invention relates to semiconductor devices and methods of fabricating semiconductor devices, and more particularly, to a non-volatile memory and a method of fabricating the same.

2. Description of the Related Art

Recently, non-volatile memories, which are programmable semiconductor memory devices, have been widely used. In the technical field of non-volatile flash memories, there has been considerable activity in the miniaturization of memory cells for improvements in memory capacities. Floating gate type flash memories are a common type of non-volatile flash memory. In this type of flash memory, charge is stored in a floating gate surrounded by silicon oxide. Recently, flash memories of MONOS (Metal Oxide Nitride Oxide Silicon) type or SONOS (Silicon Oxide Nitride Oxide Silicon) type have also been known. In these types of flash memories, charge is stored in a silicon nitride layer called a trap layer surrounded by silicon oxide. Further, other types of non-volatile memories have been proposed.

Data is written into flash memories by injecting charge into a layer for storing charge (hereinafter, a charge storage layer) surrounded by silicon oxide film such as the floating gate or the trap layer. The charge can be retained for a long time because the charge storage layer is surrounded by a silicon oxide film that is highly insulative, thus the data is non-volatile. Data can be erased by removing the charge stored in the charge storage layer. The charge is injected into and removed from the charge storage layer through a silicon nitride film called a tunnel oxide film. There is a first method of injecting a hot carrier into the charge storage layer from the channel region. There is another method for charge injection and removal utilizing an Fowler-Nordheim (F-N) tunnel current. These methods need a high electric field in order to pass the charge through the tunnel oxide film.

A conventional NOR type flash memory with a floating gate is described in detail. FIG. 1 is a circuit diagram of a memory cell of the NOR type flash memory with a floating gate. The source (S) of a transistor (Tr) is connected to a source line (SL), and the control gate (CG) is connected to a word line (WL), the drain (D) being connected to a bit line (BL).

FIG. 2 is a cross-sectional view of the memory cell. A source region 110 and a drain region 120 are formed in a P-type silicon semiconductor substrate 100, in which the regions 110 and 120 are N-type semiconductor layers. A channel region 115 is formed between the source region 110 and the drain region 120. A floating gate 130 is provided above the channel region 115, and a control gate 140 is provided above the floating gate 130. The floating gate 130 is surrounded by a silicon oxide film 135. The silicon oxide film 135 between the channel region 115 and the floating gate 130 is a tunnel oxide film. The transistor is covered by an interlayer insulation film 150 and the bit line 160 is connected to the drain region 120 through a connection via 165. The source region 110 is connected to the source line, and the control gate 140 is connected to the word line (not shown).

Next, a description will be given of the principles of writing data into the memory cell and erasing the data therefrom. Data is written into the memory cell by injecting charge into the floating gate 130. A voltage of 0V is applied to the source region 110 via the source line and a positive voltage of, for example, 6V is applied to the drain region 120 via the bit line, while a positive voltage of, for example, 9V is applied to the control gate 140 via the word line. Applications of these voltages injects hot electrons in the channel region 115 into the floating gate 130 through the tunnel oxide film so that data can be written into the memory cell.

The data is erased by removing the electrons from the floating gate 130. The drain region 120 connected to the bit line is opened, while a positive voltage of, for example, 9.3V is applied to the P-type silicon semiconductor substrate 100 and the control gate 140 is grounded via the word line. The F-N tunnel current flows between the P-type silicon semiconductor substrate 100 and the floating gate 130, causing the electrons stored in the floating gate 130 to be removed so that data can be erased from the memory cell. Another way of erasing may be used in order to efficiently remove data and miniaturize the memory cell. This other way erases data by opening the drain region 120 connected to the bit line and applying a positive voltage of 9.3V to the P-type silicon semiconductor substrate 100 while applying a negative voltage of, for example, −9.3V to the control gate 140 via the word line.

Japanese Patent Application Publication 2001-229685 discloses a non-volatile memory having a transistor with a gate of a ferroelectric thin film. The cathode terminal of a diode is connected to the drain terminal of the transistor and the anode terminal of the diode is connected to a bit line. The art disclosed in this publication aims at preventing, by the diode between the bit line and the drain, charge from flowing out to the source line via the unselected memory cells from the bit line to which the selected memory cell is connected. Although the above publication does not describe the structures of the transistor and the diode, it is considered, from the above purpose of the invention, that the transistor and the diode are separately formed.

However, the conventional NOR type flash memory described above in regards to FIGS. 1 and 2 has a disadvantage in that the bit-line and the word line may be short-circuited and an RAC (Row and Column) failure may take place when data is erased by opening the drain region 120 connected to the bit line, applying a positive voltage equal to, for example, 9.3V to the P-type silicon semiconductor substrate 100, and applying a negative voltage equal to, for example, −9.3V to the control gate via the word line. This problem arises from the following. The P-type silicon semiconductor substrate 100 is at a positive potential, and the opened bit line 160 and connection via 165 is set, via the drain region 120, at a potential approximately equal to the potential of the P-type silicon semiconductor substrate. This results in a potential difference approximately equal to 18V between the control gate 140 and the bit line 160. When the control gate 140 and the connection via 165 become closer to each other as the memory cell is minaturized, short-circuiting due to high electric fields occurs in a region 145. This problem is not confined to the above-mentioned conventional art but may take place in other non-volatile memories in which a high voltage is used to program and erase memory cells and bit lines may be short-circuited to other lines due to miniaturization of the memory cells.

The separate arrangement of the transistor and the bit line that can be seen from the above-mentioned publication prevents miniaturization of the memory cells, and does not achieve the following objects of the present invention.

### SUMMARY OF THE INVENTION

An object of the present invention is to provide a semiconductor device and a method of fabricating the same capable of preventing a bit line from being short-circuited to another line due to a high voltage applied during programming and erasing and miniaturizing of the memory cells.

The present invention is a semiconductor device including a semiconductor substrate having a source region and a drain region; a gate formed on the semiconductor substrate; a diode having a cathode region connected to the drain region; and a bit line connected to an anode region of the diode, the drain region and the cathode region being formed by a drain/cathode common region of an N-type semiconductor region. The diode is coupled between the bit line and the drain region in the reverse direction from the bit line to the drain region so that the bit line can be prevented from being set at a potential equal to that of the semiconductor substrate. It is thus possible to prevent a high electric field from being applied between the bit line and another line thereby preventing the occurrence of short-circuiting due to the high electric field. The structure of the drain region and the cathode region commonly formed is suitable for miniaturization of memory cells. Thus, the miniaturized semiconductor devices can be realized.

The semiconductor device of the present invention may be configured so that the anode region is a P-type semiconductor region having a bottom and sides surrounded by a drain/cathode common region. By forming the anode region within the cathode region, further miniaturization of memory cells is achieved.

The semiconductor device of the present invention may further include a first silicided metal layer that contacts a surface of the gate, and a second silicided metal layer having a bottom and sides surrounded by an anode region, the second silicided metal layer being connected to the bit line. It is thus possible to prevent the anode and the cathode from being short-circuited at the time of forming the first silicided metal layer.

The semiconductor device of the present invention may further include a gate comprising a control gate and a floating gate. The semiconductor device of the present invention may also be configured so that data is erased by applying a positive voltage to the semiconductor substrate and applying a negative voltage to the control gate, while the bit line is in an open state. It is thus possible to miniaturize the memory cells of the non-volatile memory in which a large potential difference develops between the control gate and the bit line during erasing.

The present invention includes a method of fabricating a semiconductor device comprising forming, by ion implantation, a drain/cathode common region made of an N-type semiconductor in a semiconductor substrate via a first opening formed in a laminate provided on the semiconductor substrate; forming, by ion implantation, an anode region of a diode made of a P-type semiconductor in the drain/cathode common region through a second opening formed in the laminate, the anode region having a bottom and sides surrounded by the drain/cathode common region; and connecting the anode region to a bit line. It is thus possible to provide a method of fabricating a semiconductor device in which short-circuiting between the bit line and another bit line can be prevented and miniaturization can be realized.

The method of the present invention may further include forming a first sidewall on a side of the first opening after the ion implantation for forming the drain/cathode common region so that the second opening is defined. The second opening may be self-aligned with the first opening. This contributes to simplifying the process and achieving further miniaturization.

The method of the present invention may be configured so that the first opening is located between gates of adjacent transistors. The arrangement of the first opening between the gates of the adjacent transistors simplifies the process and enables further miniaturization of memory cells.

The method of the present invention may further include forming a third opening on a side of the second opening after the ion implantation for forming the anode region, so that a third opening is defined, and forming a first silicided metal layer by siliciding surfaces of the gates and simultaneously forming a second silicided metal layer by siliciding a surface of the anode region. It is thus possible to prevent the anode region and the cathode region from being short-circuited at the time of forming the first silicided metal layer.

### BRIEF DESCRIPTION OF THE DRAWINGS

FIG. 1 is a circuit diagram of a memory cell of a conventional NOR type flash memory with a floating gate;

FIG. 2 is a cross-sectional view of the conventional NOR type flash memory with the floating gate of FIG. 1;

FIG. 3 is a circuit diagram of a memory cell of a NOR type flash memory with a floating gate in accordance with an embodiment of the present invention;

FIG. 4 is a cross-sectional view of the NOR type flash memory with the floating gate in accordance with the embodiment of the present invention;

FIG. 5 is a cross-sectional view of a wafer observed at a (first) step of a fabrication process in accordance with an embodiment of the present invention;

FIG. 6 is a cross-sectional view of the wafer observed at a (second) step of the fabrication process in accordance with the embodiment;

FIG. 7 is a cross-sectional view of the wafer observed at a (third) step of the fabrication process in accordance with the embodiment;

FIG. 8 is a cross-sectional view of the wafer observed at a (fourth) step of the fabrication process in accordance with the embodiment;

FIG. 9 is a diagram showing an injection depth dependence of the impurity concentration in a drain/cathode common region and an anode region in accordance with the embodiment of the present invention;

FIG. 10 is a cross-sectional view of a wafer observed at a (first) step of a fabrication process in accordance with a variation of the embodiment;

FIG. 11 is a cross-sectional view of the wafer observed at a (second) step of the fabrication process in accordance with the variation of the embodiment;

FIG. 12 is a cross-sectional view of the wafer observed at a (third) step of the fabrication process in accordance with the variation of the embodiment; and

FIG. 13 is a cross-sectional view of the wafer observed at a (fourth) step of the fabrication process in accordance with the variation of the embodiment.

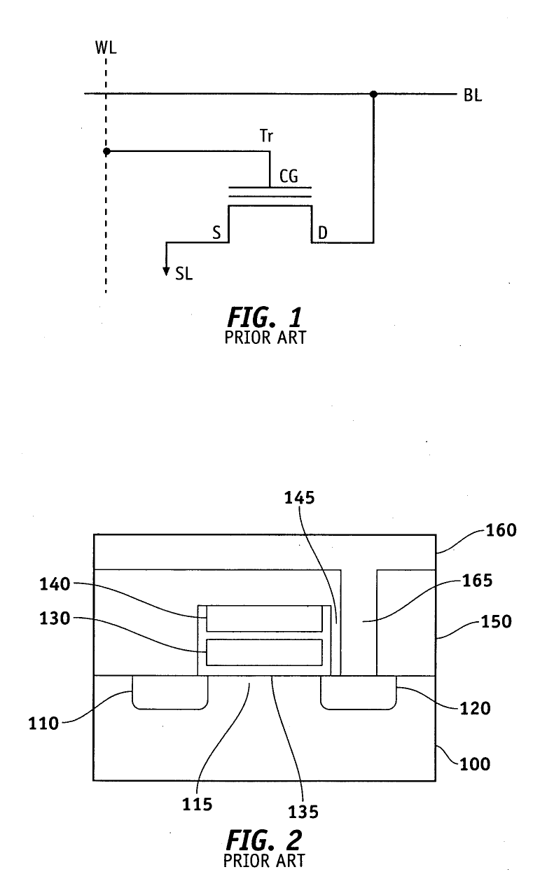

### DESCRIPTION OF THE PREFERRED EMBODIMENTS

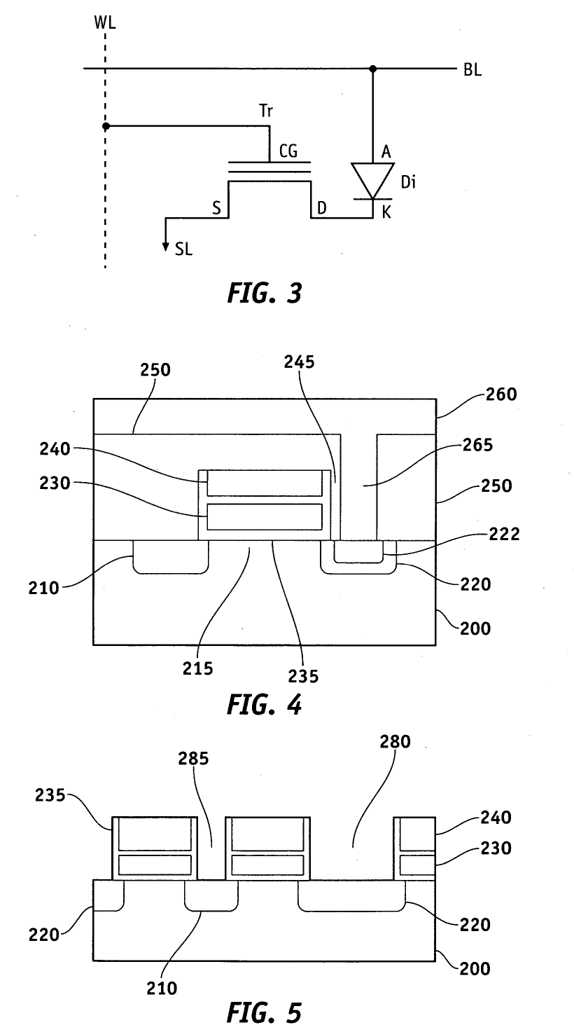

A description will now be given, with reference to the accompanying drawings, of embodiments of the present invention. FIG. 3 is a circuit diagram of a flash memory in accordance with an embodiment of the present invention. The source (S) of a transistor is connected to a source line (SL), and the gate (CG) and drain (D) thereof are connected to a word line (WL) and the cathode (K) of a diode (Di), respectively. The anode (A) of the diode (Di) is connected to the bit line (BL).

FIG. 4 is a cross-sectional view of the above memory cell in accordance with the embodiment of the present invention. A source region 210 and a drain/cathode common region 220 are formed in a P-type silicon semiconductor substrate 200, in which the regions 210 and 220 are N-type semiconductor layers. A channel region 215 is formed between the source region 210 and the drain/cathode common region 220. A floating gate 230 is formed above the channel region 215, and a control gate 240 is formed above the floating gate 230. The floating gate 230 is surrounded by a silicon oxide film 235. In accordance with the present invention, the drain/cathode common region 220 is not only the drain region of the transistor but also the cathode region of the diode. The side and lower portions of an anode region 222, which is a P-type semiconductor of the anode, are surrounded by the drain/cathode common region 220. The transistor and the diode are covered by an interlayer insulation film 250. A bit line 260 is connected to the anode region 222 via a connection via 265. The source region 210 is connected to a source line, and the control gate 240 is connected to a word line (not shown).

During data erasing, the bit line 260 is set in the open state, and a positive voltage of, for example, 9.3V is applied to the silicon semiconductor substrate 200, while a negative voltage of, for example, −9.3V is applied to the control gate 240. Even in this case, the bit line 260 and the connection via 265 are not at a positive potential. This is because the diode interposed between the drain/cathode common region 220 and the bit line 260 is reversely connected in the direction from the drain to the bit line. Thus, the potential difference between the connection via 265 and the control gate 240 can be reduced even while the distance between the connection via 265 and the control gate 240 is decreased. It is thus possible to prevent short-circuiting in a region 235 between the connection via 265 and the control gate 240 and reduce the distance between the connection via 265 and the control gate 240.

A description will now be given of a fabrication process in accordance with an embodiment of the present invention. FIGS. 5 through 8 show a fabrication process by cross sectional views of a wafer. Referring to FIG. 5, the floating gates 230 and the control gates 240 are formed above the P-type silicon semiconductor substrate 200 by a conventional fabrication method. The floating gates 230 are surrounded by the silicon oxide film 235. A first opening 280 is formed in the laminate in a position in which the drain/cathode common region is to be formed. A fourth opening 285 is formed in a laminate including layers from which the floating gates 230 and the control gate 240 are obtained. The fourth opening 285 is located at a position where the source region is to be formed. The fourth opening 285 has a size smaller than the first opening 280. Arsenic (As) ions are implanted through the fourth opening 285 and the first opening 280, and the wafer is thermally treated, so that the source region 210 and the drain/cathode common region 220 can be formed. For example, ions may be implanted at a power of 20 keV and a dose of 4×10¹⁴ cm⁻².

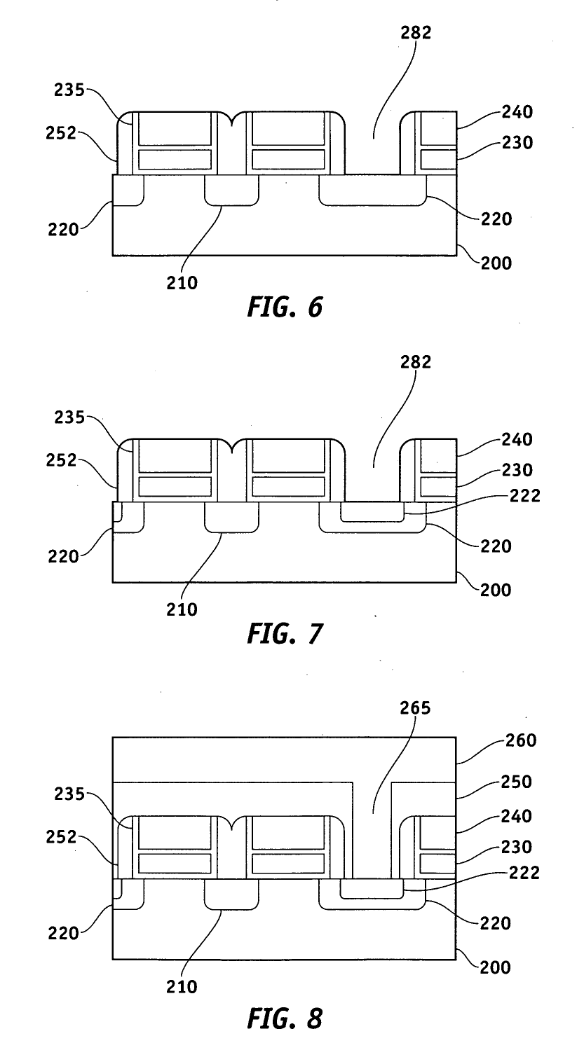

Next, referring to FIG. 6, first sidewalls 252 formed by an insulator film are formed along the sides of the first opening 280 and the fourth opening 285 in a manner well-known to those skilled in the art. In the sidewall formation method, a silicon nitride film or the like is grown on the laminate forming the openings by CVD, and the front surface of the wafer is anisotropically etched by dry etching, so that sidewalls of silicon nitride remain along the sides of the openings. The first sidewall 252 is, for example, a silicon nitride film and is, for example, 90 nm wide. A second opening 282 is formed above the drain/cathode common region 220 and is located between the adjacent first sidewalls 252. No opening exists over the source region 210 because the first sidewalls 252 on opposing sides of the fourth opening 285 are brought into contact with each other so as to form no opening.

Referring to FIG. 7, in accordance with the present invention, ions of boron fluoride are implanted through the second opening 282, and the wafer is thermally treated, so that anode regions 222 formed by the P-type semiconductor can be formed. For example, ions are implanted at a power of 20 keV and a dose of 4×10¹⁴ cm⁻².

Finally, as shown in FIG. 8, the interlayer insulation film 250 is formed on the transistor and the diode by a conventional process, and the bit line 260 is formed after formation of a connection via 265. The interlayer insulation film 250 may be, for example, a silicon oxide film, and the connection via 265 and the bit line 260 may be made of aluminum (Al) or copper (Cu). The bit line 260 is connected to the anode region 222 of the diode through the connection via 265. Then, conventional processing is further performed to complete the flash memories.

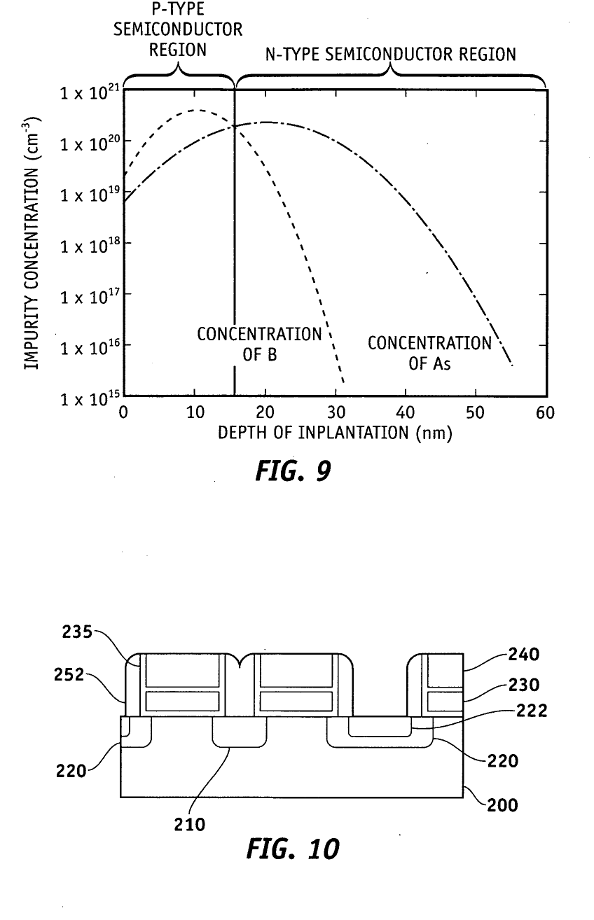

FIG. 9 shows implantation depth dependencies of arsenic (As) and boron (B) in the drain/cathode common region 220 and the anode region 222 in accordance with the exemplary conditions mentioned above. A P-type semiconductor region is available in a region shallower than approximately 16 nm, and an N-type semiconductor region is available in a region deeper than approximately 16 nm. Thus, the desired diode is formed.

FIGS. 10 through 13 show a fabrication process in accordance with a variation of the above-mentioned process. This variation is intended to reduce the resistance of the control gate and employ a first silicided metal layer on the surface of the control gate. In this variation, when the first silicided metal layer is formed, the entire surface of the anode region is silicided, which prevents the anode region and the cathode region from being short-circuited.

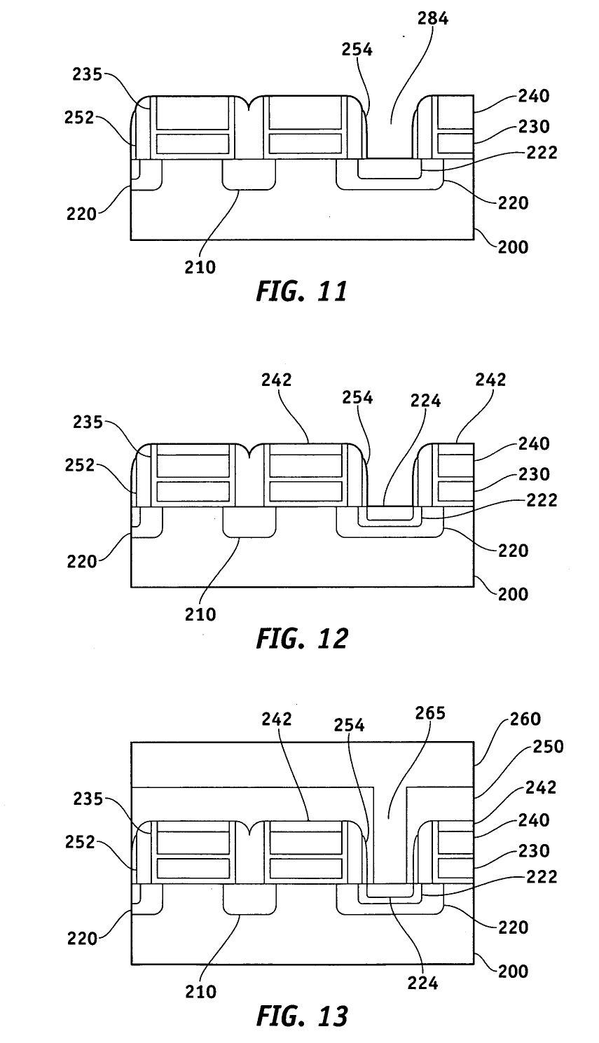

Initially, the structure shown in FIG. 10 may be formed in accordance with the aforementioned fabrication process as shown in FIGS. 5 through 7. Thereafter, referring to FIG. 11, second sidewalls 254 are formed along the side surfaces of the first sidewalls 252 by any well-known sidewall fabrication methods. This results in a third opening 284. The second sidewalls 254 may be formed by a silicon nitride film.

Next, referring to FIG. 12, the surfaces of the control gates 240 are silicided, which results in first silicided metal layers 242. At this time, the surface of the anode region 222 that faces the third opening 284 is also silicided and a resultant second silicided metal layer 224 is formed. The silicided process may be performed, for example, by depositing a layer of cobalt (Co) or titanium (Ti) by sputtering and then thermally treating the layer.

Finally, referring to FIG. 13, the interlayer insulation film 250 is formed on the transistor and the diode as described above, and the bit line 260 is formed after formation of the connection via 265. Thus, the bit line 260 is connected to the second silicided metal layer 224 via the connection via 265. Then, conventional processing is further performed to complete the flash memories.

In accordance with this variation, the third opening 284 is narrower than the anode region 222 so that the second silicided metal layer 224 cannot be brought into contact with the drain/cathode common region 220 thereby preventing the diode from being short-circuited.

Embodiments of the present invention have been described in detail. However, the present invention is not limited to the specifically described embodiments, and various variations and modifications may be made within the scope of the present invention. For example, the present invention may be applied, in addition to the NOR type flash memory with the floating gates as described above, to flash memories of MONOS (Metal Oxide Nitride Oxide Silicon) or SONOS (Silicon Oxide Nitride Oxide Silicon) type.

What is claimed is:

1. A semiconductor device comprising:
a semiconductor substrate having a source region and a drain region;
a gate formed on the semiconductor substrate;
a diode having a cathode region connected to the drain region; and
a bit line connected to an anode region of the diode,
the drain region and the cathode region being formed by a drain/cathode common region of an N-type semiconductor region.

2. The semiconductor device as claimed in claim 1, wherein the anode region is a P-type semiconductor region having a bottom and sides surrounded by the drain/cathode common region.

3. The semiconductor device as claimed in claim 2, further comprising a first silicided metal layer that contacts a surface of the gate, and a second silicided metal layer having a bottom and sides surrounded by the anode region, the second silicided metal layer being connected to the bit line.

4. The semiconductor device as claimed in claim 1, wherein the gate comprises a control gate and a floating gate.

5. The semiconductor device as claimed in claim 4, wherein data is erased by applying a positive voltage to the semiconductor substrate and applying a negative voltage to the control gate, while the bit line is in an open state.

6. A method of fabricating a semiconductor device comprising:
forming, by ion implantation, a drain/cathode common region made of an N-type semiconductor in a semiconductor substrate via a first opening formed in a laminate provided on the semiconductor substrate;
forming, by ion implantation, an anode region of a diode made of a P-type semiconductor in the drain/cathode common region through a second opening formed in the laminate, the anode region having a bottom and sides surrounded by the drain/cathode common region; and
connecting the anode region to a bit line.

7. The method as claimed in claim 6, further comprising forming a first sidewall on a side of the first opening after ion implantation for forming the drain/cathode common region so that the second opening is defined.

8. The method as claimed in claim 7, wherein the first opening is located between gates of adjacent transistors.

9. The method as claimed in claim 8, further comprising:
forming a third opening on a side of the second opening after ion implantation for forming the anode region, so that a third opening is defined, and
forming a first silicided metal layer by siliciding surfaces of the gates and simultaneously forming a second silicided metal layer by siliciding a surface of the anode region.
